(19) United States
(12) Patent Application Publication
(10) Pub. No.: US 2026/0225137 A1
(43) Pub. Date: Aug. 6, 2026

(54) CLEANING DEVICE AND METHOD FOR REMOVING CONTAMINATION PARTICLES FROM A SURFACE TO BE CLEANED

(71) Applicant: ASML Netherlands B.V., Veldhoven (NL)

(72) Inventors: Manis CHAUDHURI, Eindhoven (NL); Christian Gerardus Norbertus Hendricus Marie CLOIN, Eindhoven (NL); Andrei Mikhailovich YAKUNIN, Veldhoven (NL); Marcus Adrianus VAN DE KERKHOF, Helmond (NL)

(73) Assignee: ASML Netherlands B.V., Veldhoven (NL)

(21) Appl. No.: 19/128,906

(22) PCT Filed: Nov. 8, 2023
(86) PCT No.: PCT/EP2023/081109

§ 371 Date: May 9, 2025

(30) Foreign Application Priority Data
Nov. 17, 2022 (EP) 22208092.1

(51) Int. Cl. B08B 6/00; G03F 7/00

(52) U.S. Cl. CPC B08B 6/00; G03F 7/7085; G03F 7/70925

(57) ABSTRACT

A cleaning device for removing contamination particles from a surface to be cleaned. The cleaning device comprises an oxygen source configured to emit oxygen and thereby oxidize the contamination particles and the surface to be cleaned. The cleaning device comprises an electron source configured to emit electrons and thereby negatively charge oxidized contamination particles and the surface to be cleaned. The cleaning device comprises a contamination particle collector configured to receive a positive electric charge and thereby attract negatively charged contamination particles ejected from the surface to be cleaned.

### CROSS-REFERENCE TO RELATED APPLICATIONS

This application claims priority of EP application 22208092.1 which was filed on 17 Nov. 2022, and which is incorporated herein in its entirety by reference.

### FIELD

The present disclosure relates to a cleaning device and method. In particular, the present disclosure relates to a particle cleaning device and method for use in conjunction with a substrate processing apparatus and method such as, for example, a charged particle apparatus, a soft x-ray apparatus, a substrate metrology apparatus, a substrate inspection apparatus, a lithographic apparatus, etc., and associated methods.

### BACKGROUND

Substrate processing apparatus are used in the production and inspection of substrates such as, for example, in the manufacture of semiconductor devices. For example, when manufacturing semiconductor integrated circuit (IC) chips, undesired pattern defects, as a consequence of, for example, optical effects and incidental particles, inevitably occur on a substrate (i.e. wafer) or a mask during the fabrication processes, thereby reducing the yield. Monitoring the extent of the undesired pattern defects is therefore an important process in the manufacture of IC chips. More generally, the inspection and/or measurement of a surface of a substrate, or other object/material, is an important process during and/or after its manufacture. An example of substrate processing apparatus includes pattern inspection tools with a charged particle beam, which have been used to inspect substrates, for example to detect pattern defects. These tools typically use electron microscopy techniques, using electron optical systems for example in a scanning electron microscope (SEM). In an example electron optical system such a SEM, a primary electron beam of electrons at a relatively high energy is targeted with a final deceleration step in order to land on a sample at a relatively low landing energy. The beam of electrons is focused as a probing spot on the sample. The interactions between the material structure at the probing spot and the landing electrons from the beam of electrons cause electrons to be emitted from the surface, such as secondary electrons, backscattered electrons or Auger electrons. The generated secondary electrons may be emitted from the material structure of the sample. By scanning the primary electron beam as the probing spot over the sample surface, secondary electrons can be emitted across the surface of the sample. By collecting these emitted secondary electrons from the sample surface, a pattern inspection tool may obtain an image representing characteristics of the material structure of the surface of the sample. The intensity of the electron beams comprising the backscattered electrons and the secondary electrons may vary based on the properties of the internal and external structures of the sample, and thereby may indicate whether the sample has defects.

Another example of a substrate processing apparatus is a lithographic apparatus. A lithographic apparatus is a machine constructed to apply a desired pattern onto a substrate. A lithographic apparatus can be used, for example, in the manufacture of integrated circuits (ICs). A lithographic apparatus may, for example, project a pattern at a patterning device (e.g., a mask) onto a layer of radiation-sensitive material (resist) provided on a substrate.

To project a pattern on a substrate a lithographic apparatus may use electromagnetic radiation. The wavelength of this radiation determines the minimum size of features which can be formed on the substrate. A lithographic apparatus, which uses extreme ultraviolet (EUV) radiation, having a wavelength within the range 4-20 nm, for example 6.7 nm or 13.5 nm, may be used to form smaller features on a substrate than a lithographic apparatus which uses, for example, radiation with a wavelength of 193 nm.

Surfaces within a substrate processing apparatus may accumulate deposits of contamination particles over time. Contamination particles may emanate from said surfaces and travel to a substrate that is to be processed by the substrate processing apparatus. This may result in errors and/or defects in the processing of the substrate by the substrate processing apparatus, For example, lithographic surfaces within a lithographic apparatus may accumulate deposits of contamination particles over time. For example, repeated high acceleration movements of components such as the reticle support and the substrate table may generate contamination particles through friction. As another example, contamination particles may enter the lithographic apparatus from an external environment during vacuum pump-down processes. A portion of the contamination particles land on and adhere to lithographic surfaces such as the reticle, the substrate and/or one or more optical elements configured to interact with the electromagnetic radiation (e.g. illumination system or projection system mirrors or lenses). A portion of the contamination particles land on and adhere to surfaces proximate the substrate, accumulate over time, and emanate from said surfaces and travel towards the substrate. The contamination particles present on lithographic surfaces may negatively affect a performance of the lithographic apparatus. For example, contamination particles present on the reticle may negatively affect an accuracy with which the pattern of the reticle is imaged onto the substrate, which may in turn result in faulty chips being manufactured by the lithographic apparatus.

Known cleaning devices and methods may be limited in their ability to clean surfaces such as, for example, surfaces from which contamination particles emanate and travel towards a substrate to be processed by a substrate processing apparatus. Known cleaning devices and methods may be limited in their ability to clean lithographic surfaces. It is desirable to provide a cleaning device and method that obviates or mitigates one or more of the problems of the prior art, whether identified herein or elsewhere.

### SUMMARY

According to a first aspect of the present disclosure, there is provided a cleaning device for removing contamination particles from a surface to be cleaned. The cleaning device comprises an oxygen source configured to emit oxygen and thereby oxidize the contamination particles and the surface to be cleaned. The cleaning device comprises an electron source configured to emit electrons and thereby negatively charge oxidized contamination particles and the surface to be cleaned. The cleaning device comprises a contamination particle collector configured to receive a positive electric charge and thereby attract negatively charged contamination particles ejected from the surface to be cleaned.

The cleaning device may be a particle cleaning device. That is, the cleaning device may be configured to remove particles from the surface to be cleaned. The surface to be cleaned may be a critical surface. The surface to be cleaned may be a lithographic surface. That is, according an aspect of the present disclosure, there is provided a cleaning device for removing contamination particles from a lithographic surface to be cleaned. The cleaning device comprises an oxygen source configured to emit oxygen and thereby oxidize the contamination particles and the lithographic surface to be cleaned. The cleaning device comprises an electron source configured to emit electrons and thereby negatively charge oxidized contamination particles and the lithographic surface to be cleaned. The cleaning device comprises a contamination particle collector configured to receive a positive electric charge and thereby attract negatively charged contamination particles ejected from the lithographic surface to be cleaned.

The oxygen source advantageously converts contamination particles of varying materials, shapes and/or sizes into dielectric particles, and provides an oxide layer on the surface to be cleaned. The electron source advantageously bombards the dielectric particles and the oxide layer on the surface to be cleaned with electrons and thereby negatively charges the oxidized contamination particles and the oxide layer on the surface to be cleaned. The negatively charged contamination particles electromagnetically repel each other. The negatively charged surface to be cleaned electromagnetically repels the negatively charged particles. The forces generated by electromagnetic repulsion cause the negatively charged contamination particles to be ejected or “jump” from the surface to be cleaned. The contamination particle collector may be provided with a positive electric charge and thereby electromagnetically attract negatively charged contamination particles ejected from the surface to be cleaned to prevent the contamination particles from contacting and/or adhering to any other surfaces. The cleaning device advantageously functionally changes the surface properties of any particle by providing an oxide layer and also captures them as soon as they are released from the surface to be cleaned. The cleaning device acts as a fast and efficient cleanliness tool for contamination control in a substrate processing apparatus such as, for example, a charged particle apparatus, a soft x-ray apparatus, a substrate metrology apparatus, a substrate inspection apparatus, a lithographic apparatus, etc.

A sub-atmospheric pressure (i.e. a vacuum or near-vacuum) may be applied to a space containing the cleaning device and the surface to be cleaned.

The cleaning device advantageously reduces the cleanliness specification requirements of a substrate processing apparatus such as, for example, a charged particle apparatus, a soft x-ray apparatus, a substrate metrology apparatus, a substrate inspection apparatus, a lithographic apparatus, etc. For example, fewer vacuum pumps may be required to maintain a desired standard of cleanliness in the substrate processing apparatus. As another example, fewer pellicles may be required to protect components of a lithographic apparatus comprising the cleaning device, thereby reducing unwanted absorption of electromagnetic radiation in use.

The cleaning device may be configured to be positioned opposite the surface to be cleaned.

The surface to be cleaned may be a surface of a charged particle apparatus such as, for example, an electron beam system. The surface to be cleaned may be a surface of a soft x-ray apparatus. The surface to be cleaned may be a surface of a substrate metrology apparatus. The surface to be cleaned may be a surface of a substrate inspection apparatus. The surface to be cleaned may be a surface of a lithographic apparatus.

The cleaning device may be configured to form an integral part of a system comprising the surface to be cleaned. The cleaning device may be configured to be removable. For example, the cleaning device may be inserted into a system comprising the surface to be cleaned, used to clean said surface, and subsequently removed from said system.

This arrangement advantageously collects contamination particles quickly after ejection and before the contamination particles can fall and be incident upon other surfaces.

The cleaning device may comprise an actuation system configured to generate relative movement between the cleaning device and the surface to be cleaned.

The actuation system advantageously allows cleaning scans to be performed.

The oxygen source, the electron source and the contamination particle collector may be arranged with respect to each other such that the oxygen source leads the electron source in a scanning direction of the cleaning device. The oxygen source, the electron source and the contamination particle collector may be arranged with respect to each other such that the electron source leads the contamination particle collector in the scanning direction of the cleaning device.

This arrangement advantageously allows the surface to be cleaned in a single scanning motion or ‘sweep’ in the scanning direction.

The cleaning device may comprise a sensor system configured to detect a cleaning parameter. The cleaning device may comprise a controller configured to control at least one of the oxygen source, the electron source and the contamination particle collector in at least partial dependence upon the cleaning parameter.

The sensor system and controller advantageously provide automated and/or feedback driven operation of the cleaning device.

The cleaning parameter may comprise a distance between the cleaning device and the surface to be cleaned. The cleaning parameter may comprise an alignment between the cleaning device and the surface to be cleaned. The cleaning parameter may comprise a relative movement between the cleaning device and the surface to be cleaned.

The cleaning parameters advantageously ensure that appropriate conditions are satisfied for a desired level of cleaning to take place.

The contamination particle collector may be arranged at an angle relative to the oxygen source and the electron source such that an acute angle is formed between a direction in which the contamination particle collector faces and the surface to be cleaned.

This arrangement advantageously improves an ability of the contamination particle collector to attract and collect the negatively charged contamination particles.

The acute angle may be in the inclusive range of about 10° to about 75°.

The inventors have found this range of angles to be particularly effective in attracting and collecting negatively charged contamination particles.

The cleaning device may comprise a first insulator located between the oxygen source and the electron source. The cleaning device may comprise a second insulator located between the contamination particle collector and a housing of the cleaning device. The first insulator may be configured to electrically isolate the oxygen source from the electron source and/or the electrons. The second insulator may be configured to electrically isolate the housing from the contamination particle collector and/or the negatively charged contamination particles.

The insulators advantageously improve a safety of the cleaning device and reduce a risk of unwanted arcing, shorting, and/or other unwanted electrical effects.

The cleaning device may comprise a plurality of oxygen sources, electron sources and contamination particle collectors arranged in a cleaning array.

The cleaning array advantageously enables simultaneous cleaning of different areas of the surface to be cleaned, thereby reducing the amount of time required to clean the surface.

According to a second aspect of the present disclosure, there is provided a substrate processing apparatus comprising the cleaning device of the first aspect. The substrate processing apparatus may be a charged particle apparatus such as, for example, an electron beam inspection apparatus. The substrate processing apparatus may be a soft x-ray apparatus. The substrate processing apparatus may be a substrate metrology apparatus. The substrate processing apparatus may be a substrate inspection apparatus.

The substrate processing apparatus may be a lithographic apparatus. That is, according to an aspect of the present disclosure, there is provided a lithographic apparatus arranged to condition electromagnetic radiation and project a pattern from a patterning device onto a substrate. The lithographic apparatus comprises the cleaning device of the first aspect.

The cleaning device may be configured to form an integral part of the substrate processing apparatus. The cleaning device may be configured to be removable. For example, the cleaning device may be inserted into the substrate processing apparatus (such as, for example, a lithographic apparatus), used to clean the surface to be cleaned, and subsequently removed from the substrate processing apparatus.

The cleaning device advantageously allows in situ cleaning of the surface to be cleaned, thereby avoiding the need to remove the surface from the substrate processing apparatus. For example, a lithographic surface can be cleaned without interrupting a lithographic exposure or reducing a throughput of the lithographic apparatus.

The cleaning device may be configured to clean the patterning device. The cleaning device may be configured to clean the substrate. The cleaning device may be configured to clean an optical element configured to interact with the electromagnetic radiation.

The cleaning device may be configured to clean a surface from which the contamination particles emanate and travel to a substrate to be processed by the substrate processing apparatus.

The cleaning device may be configured to clean a surface proximate a patterning device. The patterning device may be configured to impart radiation with a pattern. The surface proximate the patterning device may be a surface of a support structure configured to support the patterning device.

The cleaning device may be configured to clean a surface proximate the substrate. The substrate may be configured to receive a patterned radiation beam. The surface proximate the substrate may be a surface of a substrate table configured to support the substrate.

The cleaning device may be configured to clean a voltage shielding plate. The voltage shielding plate may be configured to protect the substrate from electrical discharges and/or arcing. The voltage shielding plate may oppose the substrate. For example, the voltage shielding plate may oppose an upper surface of the substrate.

The substrate may be a semiconductor device. The semiconductor device may be fully formed. The semiconductor device may be partially formed. For example, the semiconductor device may be in the process of being manufactured. The substrate processing apparatus may be a post-processing tool.

According to a third aspect of the present disclosure, there is provided a method of removing contamination particles from a surface to be cleaned. The method comprises oxidizing the contamination particles and the surface to be cleaned. The method comprises negatively charging oxidized contamination particles and the surface to be cleaned. The method comprises using a positive electric charge to attract and thereby collect negatively charged contamination particles ejected from the surface to be cleaned.

The surface to be cleaned may be a lithographic surface. That is, according an aspect of the present disclosure, there is provided a method of removing contamination particles from a lithographic surface to be cleaned. The method comprises oxidizing the contamination particles and the lithographic surface to be cleaned. The method comprises negatively charging oxidized contamination particles and the lithographic surface to be cleaned. The method comprises using a positive electric charge to attract and thereby collect negatively charged contamination particles ejected from the lithographic surface to be cleaned.

According to a fourth aspect of the present disclosure, there is provided a method of processing a substrate comprising the method of claim the third aspect.

The method of removing contamination particles from the surface to be cleaned may be performed during operation of the substrate processing apparatus. For example, the method of removing contamination particles from the surface to be cleaned may be performed during emissions of charged particles such as, for example, electrons in a charged particle apparatus. As another example, the method of removing contamination particles from the surface to be cleaned may be performed during emissions of soft x-rays in a soft x-ray apparatus. As another example, the method of removing contamination particles from the surface to be cleaned may be performed during measurement of the substrate in a substrate metrology apparatus. As another example, the method of removing contamination particles from the surface to be cleaned may be performed during inspection of the substrate in a substrate inspection apparatus.

According to an aspect of the present disclosure, there is provided a method comprising projecting a patterned beam of radiation onto a substrate, and performing the method of the third aspect.

The method of removing contamination particles from the lithographic surface to be cleaned may be performed during projection of the patterned beam of radiation onto the substrate.

### BRIEF DESCRIPTION OF THE DRAWINGS

Embodiments of the invention will now be described, by way of example only, with reference to the accompanying schematic drawings, in which:

FIG. 1 schematically depicts a lithographic system comprising a lithographic apparatus, a radiation source and a plurality of cleaning devices in accordance with the present disclosure.

FIG. 2 schematically depicts a view from the side of a portion of the third cleaning device of FIG. 1 in accordance with the present disclosure.

FIG. 3 schematically depicts a view from above the third cleaning device of FIG. 1 in accordance with the present disclosure.

FIG. 4 shows a flowchart of a method of removing contamination particles from a surface to be cleaned (e.g. a lithographic surface) in accordance with the present disclosure.

FIG. 5 schematically depicts a view from the side of the portion of the third cleaning device of FIG. 2 when cleaning a different surface to that shown in FIG. 2 in accordance with the present disclosure.

FIG. 6 schematically depicts a view from the side of a portion of a cleaning device configured to clean a surface from which contamination particles emanate and travel to a substrate to be processed by a substrate processing apparatus in accordance with the present disclosure.

FIG. 7 schematically depicts an example configuration of a charged particle apparatus in the form of a single beam electron beam system which may comprise a cleaning device in accordance with the present disclosure.

### DETAILED DESCRIPTION

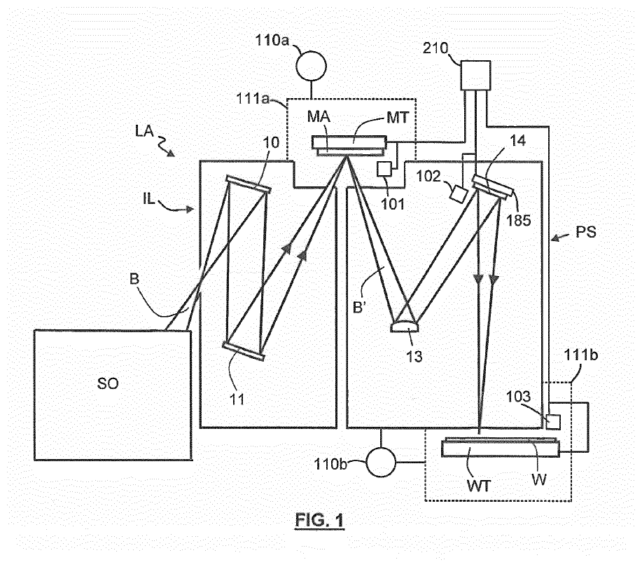

FIG. 1 schematically depicts a lithographic system comprising a radiation source SO, a lithographic apparatus LA and a plurality of cleaning devices 101-103 in accordance with the present disclosure. The radiation source SO is configured to generate an EUV radiation beam B and to supply the EUV radiation beam B to the lithographic apparatus LA. The lithographic apparatus LA comprises an illumination system IL, a support structure MT configured to support a patterning device MA (e.g., a mask), a projection system PS and a substrate table WT configured to support a substrate W.

The illumination system IL is configured to condition the EUV radiation beam B before the EUV radiation beam B is incident upon the patterning device MA. Thereto, the illumination system IL may include a faceted field mirror device 10 and a faceted pupil mirror device 11. The faceted field mirror device 10 and faceted pupil mirror device 11 together provide the EUV radiation beam B with a desired cross-sectional shape and a desired intensity distribution. The illumination system IL may include other mirrors or devices in addition to, or instead of, the faceted field mirror device 10 and faceted pupil mirror device 11.

After being thus conditioned, the EUV radiation beam B interacts with the patterning device MA. As a result of this interaction, a patterned EUV radiation beam B′ is generated. The projection system PS is configured to project the patterned EUV radiation beam B′ onto the substrate W. For that purpose, the projection system PS may comprise a plurality of mirrors 13,14 which are configured to project the patterned EUV radiation beam B′ onto the substrate W held by the substrate table WT. The projection system PS may apply a reduction factor to the patterned EUV radiation beam B′, thus forming an image with features that are smaller than corresponding features on the patterning device MA. For example, a reduction factor of 4 or 8 may be applied. Although the projection system PS is illustrated as having only two mirrors 13, 14 in FIG. 1, the projection system PS may include a different number of mirrors (e.g. six or eight mirrors).

The substrate W may include previously formed patterns. Where this is the case, the lithographic apparatus LA aligns the image, formed by the patterned EUV radiation beam B′, with a pattern previously formed on the substrate W.

A relative vacuum, i.e. a small amount of gas (e.g. hydrogen) at a pressure well below atmospheric pressure, may be provided in the radiation source SO, in the illumination system IL, and/or in the projection system PS.

The radiation source SO may be a laser produced plasma (LPP) source, a discharge produced plasma (DPP) source, a free electron laser (FEL) or any other radiation source that is capable of generating EUV radiation.

In the example of FIG. 1, the lithographic apparatus LA is configured to use EUV radiation. It will be understood that the cleaning device and method of the present disclosure is not limited to use with EUV lithographic apparatus, and may be used with other lithographic apparatus such as, for example, deep ultraviolet (“DUV”) lithographic apparatus.

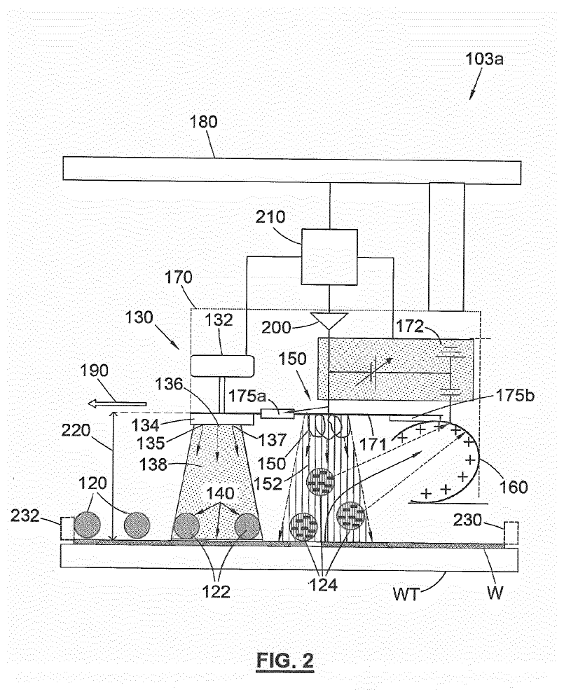

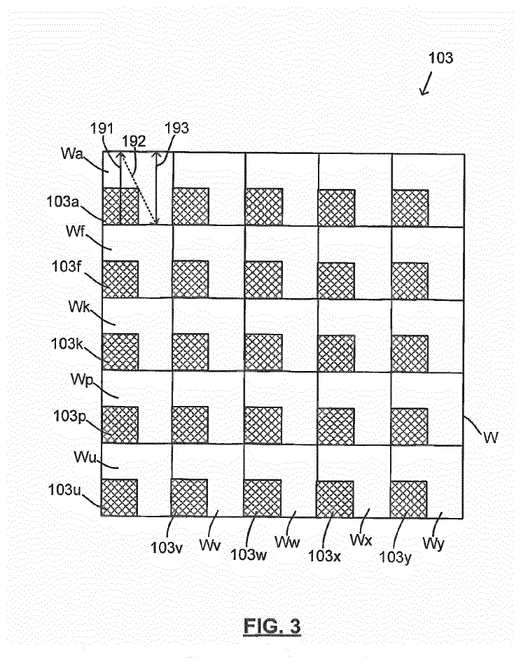

The lithographic apparatus LA of FIG. 1 comprises three cleaning devices 101-103 in accordance with the present disclosure. The lithographic apparatus LA may be provided with a greater or lesser number of cleaning devices 101-103. The cleaning devices 101-103 are substantially identical. One of the cleaning devices 103 is shown in greater detail in FIGS. 2 and 3. Each cleaning device 101-103 is configured to remove contamination particles from a lithographic surface MA, 14, W to be cleaned. A first lithographic cleaning device 101 is configured to clean the patterning device MA. A second cleaning device 102 is configured to clean an optical element 14 configured to interact with the electromagnetic radiation B′ of the lithographic apparatus LA. In the example of FIG. 1, the optical element is a mirror 14 present in the projection system PS. The second cleaning device 102 may be configured to clean other optical elements of the lithographic apparatus LA or a greater number of cleaning devices may be provided to clean other optical elements of the lithographic apparatus LA (e.g. one or more optical elements 10, 11 present in the illumination system IL). A third cleaning device 100 is configured to clean the substrate W.

The lithographic apparatus LA may comprise one or more vacuum pumps 110a-b. The vacuum pumps 110a-b may be configured to provide a sub-atmospheric pressure (i.e. a vacuum or near-vacuum) in an internal space containing the cleaning device 101-103 and the lithographic surface. In the example of FIG. 1, a first vacuum pump 110a provides a sub-atmospheric pressure in a first internal space 111a containing the first cleaning device 101 and a second vacuum pump 110b provides a sub-atmospheric pressure in a second internal space 111b containing the second and third cleaning devices 102-103. The lithographic apparatus LA may comprise a greater or lesser number of vacuum pumps 110a-b configured to provide a sub-atmospheric pressure in a greater or lesser number of internal spaces 111a-b. The sub-atmospheric pressure may assist functioning of the cleaning devices by providing an improved environment for the controlled and directionally targeted emission of oxygen and electrons as discussed in greater detail below.

FIG. 2 schematically depicts a view from the side of a portion 103a of the third cleaning device 103 of FIG. 1 in accordance with the present disclosure. The cleaning device 103 is configured to clean a lithographic surface which, in the example of FIG. 2, is the substrate W. Contamination particles 120 are adhered to the substrate W. It will be appreciated that FIG. 2 is not drawn to scale and that, in particular, the relative size of the contamination particles 120 has been increased for ease of understanding. The contamination particles 120 may be generated by, for example, high velocity and/or acceleration movements of the substrate table WT during exposures. The contamination particles 120 may have different sizes and/or may be formed of different materials having different surface properties such as electrostatic behaviour. The contamination particles 120 may comprise dielectric particles, conducting particles and semiconductor particles. For example, the contamination particles 120 may comprise materials such as Al₂O₃, SiO₂, metals, etc. The contamination particles 120 may have a size of about 1 μm or more. The contamination particles 120 may have a size of about 100 μm or less. The contamination particles 120 may have a size of about 10 μm. The cleaning device 103 is capable of removing contamination particles 120 of different sizes and materials having different surface properties as explained in more detail below.

The cleaning device 103 comprises an oxygen source 130 configured to emit oxygen 138. The oxygen source 130 may, for example, comprise an oxygen tank 132 fluidly connected to a gas output 134. The oxygen tank 132 may form part of a pre-existing oxygen provision system (not shown) configured to provide oxygen to one or more components of the lithographic apparatus LA (e.g. to provide flushing of one or more areas of the lithographic apparatus LA). The gas output 134 may comprise one or more apertures or nozzles 135-137 configured to emit oxygen in a cone-like or curtain-like jet 138. The oxygen source 130 may be configured to provide an oxygen flow of about 10 standard cubic centimetres per minute or more. The oxygen source 130 may be configured to provide an oxygen flow of about 1000 standard cubic centimetres per minute or less. The oxygen 138 reacts with the contamination particles 120 and the lithographic surface W and thereby oxidizes the contamination particles 120 and the lithographic surface W. The oxygen 138 forms an oxide layer 140 on the contamination particles 120 (thereby forming oxidized contamination particles 122) and the lithographic surface W. The oxide layer 140 may have a thickness of about 5 nm or more. The oxide layer 140 may have a thickness of about 30 nm or less. The presence of the oxide layer 140 functionally changes the surface properties of all the different sizes and types of contamination particles 120 present on the lithographic surface W such that the oxidized contamination particles 122 behave as dielectric particles. Various parameters such as, for example, temperature, oxidation diffusion rate, material properties of the contamination particles 120 may at least partially determine the formation of the oxide layer 140. The temperature may correspond to the typical temperature of a lithographic apparatus LA environment. The temperature may be about 20° C. or more. The temperature may be about 40° C. or less. A speed with which the cleaning device 103 is moved with respect to the lithographic surface W may at least partially determine a thickness of the oxide layer 140.

The cleaning device 103 further comprises an electron source 150 configured to emit electrons 152. The electron source 150 may, for example, comprise a filament configured to emit electrons 152 upon receipt of an electric current. The electron source 150 may take other forms. For example, the electron source 150 may be an electron gun. The electron source 150 may be configured to provide an electron beam 152 having an energy of about 10 eV or more. The electron source 150 may be configured to provide an electron beam 152 having an energy of about 100 eV or less. The electron source 150 may be configured to provide an electron beam 152 having an energy of about 50 eV. The energy of the electron beam 152 may be limited to avoid arcing. The electrons 152 confer a negative electric charge upon the oxidized contamination particles 122 (thereby producing negatively charged contamination particles 124) and the lithographic surface W. The electron source 150 may be referred to as an ionizer. The presence of the oxide layer 140 and the associated dielectric surface properties of the oxidized contamination particles 122 advantageously allows the electrons 152 to confer a negative electric charge upon the oxidized contamination particles 122 regardless of the contamination particles' 120 original surface properties. The negatively charged contamination particles 124 electromagnetically repel each other. The negatively charged lithographic surface W electromagnetically repels the negatively charged contamination particles 124. The forces generated by electromagnetic repulsion cause the negatively charged contamination particles 124 to be ejected or ‘jump’ from the lithographic surface W. That is, the negatively charged contamination particles 124 no longer adhere to the lithographic surface W.

The cleaning device 103 further comprises a contamination particle collector 160. The contamination particle collector 160 may comprise a vessel. The vessel may be generally bowl-shaped. The contamination particle collector 160 may be formed of a conductor such as, for example, aluminum or stainless steel. The contamination particle collector 160 is configured to receive a positive electric charge and thereby electromagnetically attract the negatively charged contamination particles 124 that have been ejected from the lithographic surface W. The contamination particle collector 160 may be configured to receive a bias of about 10 V or more. The contamination particle collector 160 may be configured to receive a bias of about 100 V or less. The electromagnetic attraction may act upon the negatively charged contamination particles 124 immediately or shortly after they are ejected from the lithographic surface W. The electromagnetic attraction causes the negatively charged contamination particles 124 to move towards and adhere to the contamination particle collector 160 before the negatively charged contamination particles 124 are able to either move back towards and adhere to the lithographic surface W or move towards and adhere to any other lithographic surface present in the lithographic apparatus LA. The contamination particle collector 160 may provide an electrostatic force which attracts the negatively charged contamination particles 124. The contamination particle collector 160 may be emptied and/or cleaned at regular intervals to remove the collected contamination particles. The contamination particle collector 160 may be positioned closer to the lithographic surface W than the oxygen source 130 or the electron source 150. The contamination particle collector 160 may be positioned about half way between the lithographic surface W and the oxygen and electron sources 130, 150. For example, contamination particle collector 160 may be positioned about 0.5 mm away from the lithographic surface W.

The cleaning device 103 is configured to be positioned opposite the lithographic surface W to be cleaned. This arrangement advantageously improves the attraction and collection of negatively charged contamination particles 124 quickly after ejection from the lithographic surface W and before the negatively charged contamination particles 124 can travel and adhere to any lithographic surfaces. In the example of FIG. 2, the cleaning device 103 comprises a housing 170 configured to house the oxygen source 130, the electron source 150 and the contamination particle collector 160. The housing 170 comprises one or more openings for allowing the emission of oxygen 138 and electrons 152 towards the lithographic surface W and for allowing the attraction of negatively charged contamination particles 124 towards the contamination particle collector 160. The oxygen source 130, electron source 150 and contamination particle collector 160 may be arranged along and supported by a base 171 of the housing 170. In the example of FIG. 2, the oxygen source 130 and the electron source 150 and the base 171 are downwardly facing and the lithographic surface W is upwardly facing such that the cleaning device 103 and the lithographic surface W oppose each other along a vertical axis. It will be appreciated that different lithographic apparatus LA may be arranged in different ways, and that the cleaning device 103 and the lithographic surface W may oppose each other along different directions or axes. For example, in the lithographic apparatus of FIG. 1 it can be seen that that the second cleaning apparatus 102 opposes its associated lithographic surface 14 along a non-vertical and non-horizontal axis (e.g. a substantially diagonal axis). As another example, the first cleaning device 103 opposes its associated lithographic surface MA along a vertical axis. However, in contrast to the third cleaning device 103, the first cleaning device 101 faces upwardly whereas its associated lithographic surface MA faces downwardly. In the example of FIG. 2, the contamination particle collector 160 is arranged at an angle relative to the oxygen source 130 and the electron source 150 such that the contamination particle collector 160 faces the lithographic surface W at an acute angle relative to the lithographic surface W. The acute angle formed between the direction in which the contamination particle collector 160 faces and the lithographic surface W may, for example, be about 10° or more. The acute angle formed between the direction in which the contamination particle collector 160 faces and the lithographic surface W may, for example, be about 75° or less.

The cleaning device 103 comprises an actuation system 180, WT configured to generate relative movement between the cleaning device 103 and the lithographic surface W. In the example of FIG. 2, the actuation system 180, WT comprises an actuator 180 which is configured to move the cleaning device 103 and the substrate table WT which is configured to move the substrate W. The actuator 180 may take any suitable form such as, for example, a robotic arm, a step-and-scan stage (such as the step and scan stages used to move the patterning device MT and the substrate W), etc. The actuation system 180, WT may be capable of providing both coarse and fine adjustments of the relative positioning of the cleaning device 103 and the lithographic surface W. The actuation system 180, WT may consist solely of either the actuator 180 or the substrate table WT. It will be appreciated that the actuation system 180, WT may take other forms. For example, with reference to FIG. 1, the actuation system of the first cleaning device 101 may comprise an actuator 180 of the kind shown in FIG. 2 and/or the support structure MT configured to support the patterning device MA. As another example, the actuation system of the second cleaning device 102 may comprise an actuator 180 of the kind shown in FIG. 2 and/or an optical element actuator 185 configured to move an optical element 14. Each actuation system 180, MT, 185, WT may be configured such that cleaning scans of the respective lithographic surfaces MA, 14, W may be performed. An example of a cleaning scan direction 190 is shown in FIG. 2.

In the example of FIG. 2, the actuator 180 moves the cleaning device 103 in a scanning direction 190 relative to the lithographic surface W. The oxygen source 130, the electron source 150 and the contamination particle collector 160 are arranged with respect to each other such that the oxygen source 132 leads the electron source 150 in the scanning direction 190 of the cleaning device 103. This arrangement ensures that contamination particles 120 present on the lithographic surface W first undergo exposure to oxygen 138 emitted by the oxygen source 130, thereby allowing the first step of the cleaning process (i.e. the formation of the oxide layer 140) to be performed first during a cleaning scan. The electron source 150 leads the contamination particle collector 160 in the scanning direction 190 of the cleaning device 103. That is, the electron source 150 follows the oxygen source 130 in the scanning direction 190. This arrangement ensures that oxidized contamination particles 122 (having already been exposed to oxygen 138 by the oxygen source 130) undergo exposure to electrons 152 emitted by the electron source 150, thereby allowing the second step of the cleaning process (i.e. forming the negatively charged contamination particles 124) to be performed second during a cleaning scan. Finally, the contamination particle collector 160 follows the electron source 150 in the scanning direction 190, thereby allowing the third step of the cleaning process (i.e. electromagnetically attracting the negatively charged contamination particles 124 towards the contamination particle collector 160) to be performed third during a cleaning scan. This arrangement advantageously allows at least a portion or strip of the lithographic surface W to be cleaned in a single scanning motion or ‘sweep’ in the scanning direction 190.

The cleaning device 103 comprises a sensor system 200 configured to detect a cleaning parameter. The sensor system 200 may comprise pre-existing sensors present in the lithographic apparatus LA. The sensor system 200 may comprise an optical sensor such as, for example, a time-of-flight sensor or a camera. The cleaning device 103 comprises a controller 210 configured to control at least one of the oxygen source 130, the electron source 150 and the contamination particle collector 160 in at least partial dependence upon the cleaning parameter.

The cleaning parameter may comprise a distance 220 between the cleaning device 103 and the lithographic surface W. The sensor system 200 may monitor the distance 220 between the cleaning device 103 and the lithographic surface W, and the controller 210 may activate or deactivate one or more of the oxygen source 130, the electron source 150 and the contamination particle collector 160 in at least partial dependence upon the distance 220. For example, the controller 220 may be configured to activate the oxygen source 130, the electron source 150 and the contamination particle collector 160 when the distance 220 detected by the sensor system 200 is about 1 mm or less. The inventors have found that this distance advantageously provides rapid formation of the oxide layer 140 whilst also reducing unwanted dispersion of oxygen 138 to other areas.

The cleaning parameter may be an alignment between the cleaning device 103 and the lithographic surface W. The sensor system 200 may monitor an alignment (i.e. a relative positioning) between the cleaning device 103 and the lithographic surface W and detect a cleaning scan start position 230 and a cleaning scan end position 232. The controller 220 may be configured to activate one or more of the oxygen source 130, the electron source 150 and the contamination particle collector 160 when the sensor system 200 indicates that the cleaning device 103 has reached the cleaning scan start position 230. The controller 220 may be configured to sequentially activate the oxygen source 130, the electron source 150 and the contamination particle collector 160 as each of the oxygen source 130, the electron source 150 and the contamination particle collector 160 reaches the cleaning scan start position 230. The controller 220 may be configured to deactivate one or more of the oxygen source 130, the electron source 150 and the contamination particle collector 160 when the sensor system 200 indicates that the cleaning device 103 has reached the cleaning scan end position 232. The controller 220 may be configured to sequentially deactivate the oxygen source 130, the electron source 150 and the contamination particle collector 160 as each of the oxygen source 130, the electron source 150 and the contamination particle collector 160 reaches the cleaning scan end position 232.

The cleaning parameter may be a relative movement between the cleaning device 103 and the lithographic surface W. The sensor system 200 may monitor a speed of the cleaning device 103 relative to the lithographic surface W. The sensor system 200 may monitor a direction of movement 190 of the cleaning device 103 relative to the lithographic surface W. For example, the sensor system 200 may monitor a speed and direction 190 of a cleaning scan. The controller 220 may be configured to activate one or more of the oxygen source 130, the electron source 150 and the contamination particle collector 160 when the sensor system 200 indicates that the cleaning device 103 has reached a desired scan speed and/or direction 190 relative to the lithographic surface W. For example, the controller 220 may control an oxygen flow rate provided by the oxygen source 130, an electric current (e.g. between about 100 μA and about 1000 μA) provided to the electron source 150, a bias provided to the contamination particle catcher 160, etc. The controller 220 may be configured to deactivate one or more of the oxygen source 130, the electron source 150 and the contamination particle collector 160 when the sensor system 200 indicates that the cleaning device 103 has deviated from the desired scan speed and/or direction 190 relative to the lithographic surface W.

The cleaning device 100c comprises a power source 172. The power source 172 is configured to provide power to the electron source 150 and the contamination particle collector 160. When the power source 172 provides power to the electron source 150, the electron source 1540 emits electrons 152. When the power source 172 provides power to the contamination particle collector 160, the contamination particle collector 160 becomes positively charged. The controller 210 may be configured to control the power source 172 in at least partial dependence upon the cleaning parameter detected by the sensing system 200. The power source 172 may be configured to operate at an energy of 1 Wh or less.

The cleaning device 103 comprises one or more insulators 175a, b. In the example of FIG. 2, the cleaning device comprises a first insulator 175a located between the oxygen source 130 and the electron source 150 and a second insulator 175b located between the contamination particle collector 160 and the base 171 of the housing 170. The cleaning device 103 may comprise a greater or lesser number of insulators 175a, b. The first insulator 175a is configured to electrically isolate the oxygen source 130 from the electron source 150 and/or the electrons 152. The second insulator 175b is configured to electrically isolate the housing 170 from the contamination particle collector 160 and/or the negatively charged contamination particles 124.

FIG. 3 schematically depicts a view from above the third cleaning device 103 of FIG. 1 in accordance with the present disclosure. As can be seen from FIG. 3, the cleaning device 103 comprises a plurality of oxygen sources, electron sources and contamination particle collectors (i.e. multiple portions 103a-y of the cleaning device 103) arranged in a cleaning array. In the example of FIG. 3, the cleaning array comprises a five-by-five square array of twenty five portions 103a-y of the cleaning device 103. Each portion 103a-y of the cleaning device 103 is configured to clean a respective portion Wa-y of the lithographic surface W. Each cleaning portion 103a-y may comprise its own oxygen source, electron source, contamination particle collector and sensor system. A greater or lesser number of portions 103a-y may be provided. Different shapes of arrays may be used. In general, the number of portions 103-y and/or the shape of the cleaning array may be selected based in at least partial dependence upon a shape and/or size of the lithographic surface to be cleaned.

The actuation system (not shown) is configured to move the entire cleaning array such that each portion 103a-y of the cleaning device 103 moves in unison. An example of a three-stage cleaning scan 191-193 is shown in FIG. 3. It will be appreciated that the portions 103a-y of the cleaning device 103 may be moved in different directions and/or scanned a different number of times as required to clean a particular lithographic surface W. In the example of FIG. 3, a starting scan position of a portion 103a-y of the cleaning device 103 is located at a bottom-left corner of a respective portion Wa-y of the lithographic surface W. The starting scan position may vary. A first scan stage 191 comprises moving the portions 103a-y of the cleaning device 103 forwards in a plane parallel to the lithographic surface W such that the portions 103a-y of the cleaning device 103 move from the bottom-left corner to the top-left corner of the portions Wa-y of the lithographic surface W. The oxygen sources, the electron sources and the contamination particle collectors of the portions 103a-y of the cleaning device 103 are active during the first scan stage 191. A second scan stage 192 comprises moving the portions 103a-y of the cleaning device 103 backwards and to the right in the plane parallel to the lithographic surface W such that the portions 103a-y of the cleaning device 103 move from the top-left corner to the bottom-right corner of the portions Wa-y of the lithographic surface W. The oxygen sources, the electron sources and the contamination particle collectors of the portions 103a-y of the cleaning device 103 may be inactive during the second scan stage 192. A third scan stage 193 comprises moving the portions 103a-y of the cleaning device 103 forwards in the plane parallel to the lithographic surface W such that the portions 103a-y of the cleaning device 103 move from the bottom-right corner to the top-right corner of the portions Wa-y of the lithographic surface W. The oxygen sources, the electron sources and the contamination particle collectors of the portions 103a-y of the cleaning device 103 are active during the third scan stage 193. In the example of FIG. 3, an end scan position of a portion 103a-y of the cleaning device 103 is located at a bottom-right corner of a respective portion Wa-y of the lithographic surface W. The end scan position may vary.

The cleaning array advantageously enables simultaneous cleaning of multiple different areas Wa-y of the lithographic surface W, thereby reducing the amount of time required to clean the lithographic surface W. For example, the section of the lithographic surface W shown in FIG. 3 may have surface area of about 10 cm by about 10 cm. That is, each portion Wa-y of the lithographic surface W may have a surface area of about 2 cm by about 2 cm. Each portion 103a-y of the cleaning device may have dimensions of about 1 cm by about 1 cm by about 1 cm. The actuation system 180 may, for example, be configured to provide a movement speed of about 1 meter per second between the cleaning device 103 and the lithographic surface W. The cleaning device 103 may be capable of cleaning the section of the lithographic surface W shown in FIG. 3 by performing the first to third scan stages 191-193 in about 1 ms or less.

In the example of FIG. 3, the first and third scan stages 191, 191 of the cleaning array are sufficient for cleaning the entire lithographic surface W.

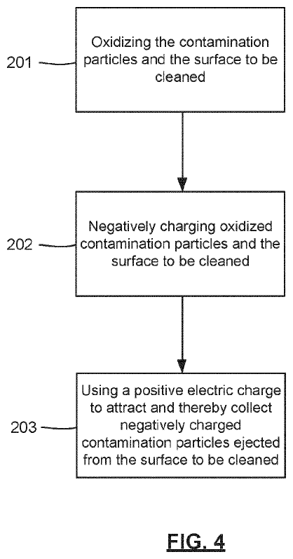

FIG. 4 shows a flowchart of a method of removing contamination particles from a surface to be cleaned (e.g. a lithographic surface). A first step 201 of the method comprises oxidizing the contamination particles and the surface to be cleaned. A second step 202 of the method comprises negatively charging oxidized contamination particles and the surface to be cleaned. A third step 203 of the method comprises using a positive electric charge to attract and thereby collect negatively charged contamination particles ejected from the surface to be cleaned.

The method of FIG. 4 may form part of a method of processing a substrate. For example, the method of removing contamination particles from the surface to be cleaned may be performed during operation of a substrate processing apparatus. For example, the method of removing contamination particles from the surface to be cleaned may be performed during emissions of charged particles such as, for example, electrons in a charged particle apparatus. As another example, the method of removing contamination particles from the surface to be cleaned may be performed during emissions of soft x-rays in a soft x-ray apparatus. As another example, the method of removing contamination particles from the surface to be cleaned may be performed during measurement of the substrate in a substrate metrology apparatus. As another example, the method of removing contamination particles from the surface to be cleaned may be performed during inspection of the substrate in a substrate inspection apparatus.

The method of FIG. 4 may be used in combination with performing a lithographic exposure, e.g. when using the lithographic apparatus LA of FIG. 1. For example, such a method may comprise projecting the patterned beam of radiation B′ onto the substrate W and performing the method of FIG. 4. For example, the method of FIG. 4 (i.e. the method of removing contamination particles 120 from a surface W to be cleaned) may be performed during projection of the patterned beam of radiation B′ onto the substrate W.

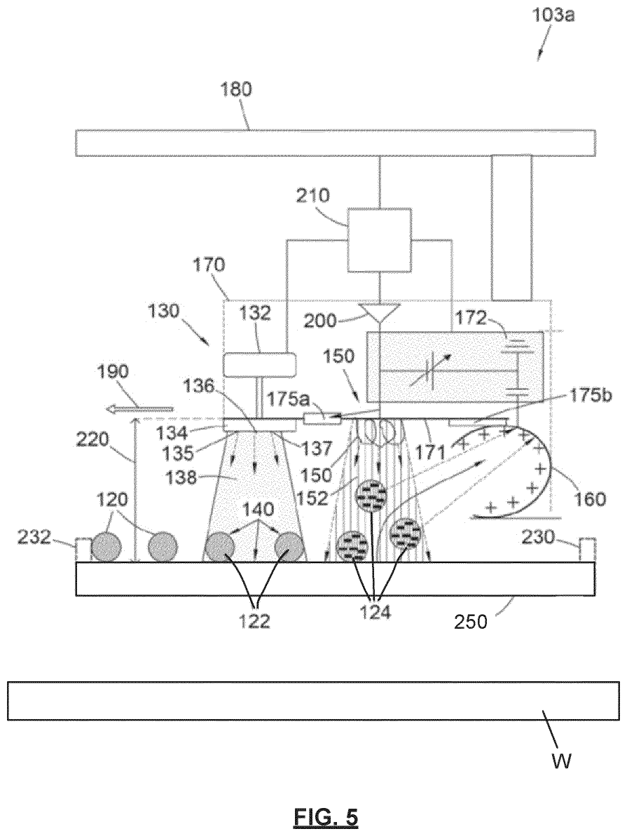

FIG. 5 schematically depicts a view from the side of the portion of the third cleaning device of FIG. 2 when cleaning a different surface 250 to that shown in FIG. 2 in accordance with the present disclosure. The cleaning device 103a is configured to clean a surface 250 from which contamination particles 120 emanate and travel to a substrate W to be processed by a substrate processing apparatus (not shown) in accordance with the present disclosure. In the example of FIG. 5, the surface 250 from which contamination particles 120 emanate and travel to the substrate W to be processed by a substrate processing apparatus is a surface proximate the substrate W, and the substrate processing apparatus is the lithographic apparatus LA of FIG. 1. For example, the surface 250 may be a metallic area proximate the substrate W upon which contamination particles 120 may accumulate and subsequently emanate and travel towards the substrate W. Any of the cleaning devices 101-103 of FIG. 1 may be configured to clean any surface of the lithographic apparatus LA. For example, the first cleaning device 101 may be configured to clean a surface (not shown) proximate the patterning device MA from which contamination particles may otherwise emanate and travel to the patterning device MA. A surface proximate the substrate W and/or the patterning device MA from which contamination particles 120 may emanate towards the substrate W and/or the patterning device MA may be referred to in the art as a critical surface.

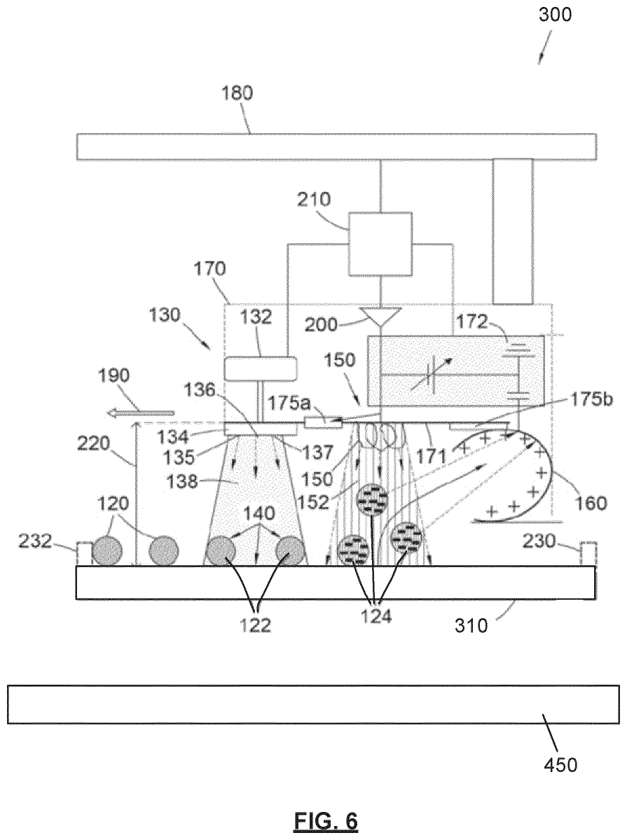

FIG. 6 schematically depicts a view from the side of a portion of a cleaning device 300 configured to clean a surface 310 from which contamination particles 120 emanate and travel to a substrate 450 to be processed by a substrate processing apparatus (not shown) in accordance with the present disclosure. The cleaning device 300 of FIG. 5 is identical to the cleaning device 103a of FIG. 2, and like reference numerals have been used to identify like features (which will not be described again for conciseness). In summary, contamination particles 120 are adhered to the surface to be cleaned 310. It will be appreciated that FIG. 6 is not drawn to scale and that, in particular, the relative size of the contamination particles 120 has been increased for ease of understanding. The contamination particles 120 may be generated by, for example, high velocity and/or acceleration movements of components of the substrate processing apparatus during substrate processing. The oxygen 138 reacts with the contamination particles 120 and the surface to be cleaned 310 and thereby oxidizes the contamination particles 120 and the surface to be cleaned 310. The electrons 152 confer a negative electric charge upon the oxidized contamination particles 122 (thereby producing negatively charged contamination particles 124) and the surface to be cleaned 310. The negatively charged contamination particles 124 electromagnetically repel each other. The negatively charged surface to be cleaned 310 electromagnetically repels the negatively charged contamination particles 124. The forces generated by electromagnetic repulsion cause the negatively charged contamination particles 124 to be ejected or ‘jump’ from the surface to be cleaned 310. That is, the negatively charged contamination particles 124 no longer adhere to the surface to be cleaned 310. The contamination particle collector 160 is configured to receive a positive electric charge and thereby electromagnetically attract the negatively charged contamination particles 124 that have been ejected from the surface to be cleaned 310. The electromagnetic attraction causes the negatively charged contamination particles 124 to move towards and adhere to the contamination particle collector 160 before the negatively charged contamination particles 124 are able to either move back towards and adhere to the surface to be cleaned 310 or move towards and adhere to any other surface, such as the substrate W.

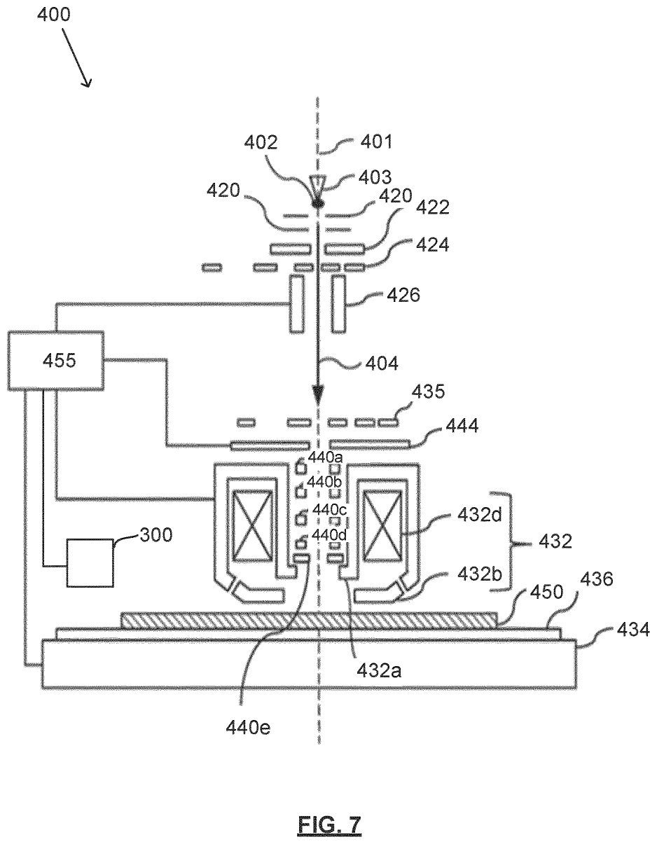

In contrast to the arrangement of FIG. 2, the cleaning device 300 of FIG. 5 forms part of a substrate processing apparatus other than a lithographic apparatus, and is used to clean a surface 310 other than a lithographic surface. In the example of FIG. 6, the surface 310 from which contamination particles 120 emanate and travel to the substrate 450 to be processed by a substrate processing apparatus is a voltage shielding plate 310, and the substrate processing apparatus is a charged particle apparatus (an example of which is shown and described with reference to FIG. 7). The voltage shielding plate 310 may be configured to protect the substrate 450 from unwanted electrical discharges and/or arcing. The voltage shielding plate 310 may oppose the substrate 450. For example, the voltage shielding plate 310 may oppose an upper surface of the substrate 450. In the arrangement of FIG. 6, the cleaning device 300 acts to clean a critical surface of a substrate processing apparatus before the contamination particles 120 on said critical surface can travel towards the substrate 450. As such, the cleaning device 300 acts as a preventative measure in protecting the substrate 450 from defects during processing and/or post-processing. The substrate processing apparatus may be a charged particle apparatus such as, for example, an electron beam apparatus. The substrate processing apparatus may be a soft x-ray apparatus. The substrate processing apparatus may be a substrate metrology apparatus. The substrate processing apparatus may be a substrate inspection apparatus.

A charged particle apparatus typically comprises a charged particle source for emitting charged particles, an electron-optical device for controlling and redirecting the charged particles, a substrate holder for positioning a substrate to interact with the charged particles, and, in the case of an inspection or metrology system, a detector for capturing interaction products that may occur due to the interaction between the charged particles and the substrate. Charged particle apparatus may be used for the assessment of substrates, for example inspection of a semiconductor wafer to detect e.g. defects in a pattern on and/or in the semiconductor wafer, or may be used for metrology for measuring dimensions of features constituting the pattern on and/or in the semiconductor wafer.

The particle source, in use, typically emits an expanding beam of charged particles, such as electrons. The electron beam originating from the particle source and reaching the substrate is also often referred to as the primary beam of the charged particle system.

The electron-optical device may be configured to focus the charged particles (or primary beam) onto the substrate (or semiconductor wafer), may be configured to reduce aberrations that may be present in the charged particle beam (or primary beam), and/or may be configured to change a beam-path of the charged particle beam (or primary beam), for example to scan the charged particle beam across the substrate or to temporarily blank the beam (which refers to redirecting the primary beam into a beam dump to temporarily avoid the primary beam from reaching the substrate). To enable the electron-optical device to control and redirect the charged particles, the electron-optical device may comprise magnetic and/or electrostatic lenses and deflector elements in many different combinations. Typically, the expanding beam of charged particles coming from a source may first be collimated and subsequently focused onto a substrate by the electron-optical device. The electron-optical device may be configured to control or redirect a single charged particle beam (further also referred to as a single beam system) or multiple charged particle beams simultaneously (further also referred to as a multi-beam system). In the case of multiple charged particle beams, the electron-optical device may comprise a macroscopic lenses in which a single macroscopic lens interacts with a plurality of the multiple charged particle beams, or may comprise one or more individual lens columns for each individual beam in the multiple charged particle beams, or combinations of macroscopic lenses and while or partial individual lens columns. A multi-beam system may comprise a single source that emits the expanding beam of charged particles which may be chopped into multiple individual beams that are redirected and focused onto the substrate by the electron-optical device. Alternatively, the multi-beam system may comprise multiple sources that each emit primary beams that are redirected and focused onto the substrate (which may be referred to as a multi-column system). Each primary beam in the multi-column system may be chopped into multiple individual beams, such that each column in the multi-column system comprises a multi-beam system.

During the interaction between the primary beam(s) and the substrate, interaction products are emitted from the substrate. In the case of an e-beam system, the interaction products may include X-rays and/or signal particles such as secondary electrons and/or backscatter electrons. The electron-optical device may be configured to assist the secondary electrons and/or the backscatter electrons to reach the one or more detectors that may be present in the charged particle system. The electron-optical device may, for example, comprise a beam separator (such as a Wien filter) to separate the primary beam electrons from the signal particles coming from the substrate and redirect (at least some of) the signal electrons into a secondary beam column that focuses these redirected signal electrons onto the detector. Alternatively, the detector may be integrated into (or even be part of) the electron-optical device, such as one or more in-lens detectors. In such configurations, the electron-optical device may comprise elements that are configured to ensure that the signal electrons reach the one or more detectors. The electron-optical device may comprise one or more integrated detectors, e.g. on a part of the electron-optical device that faces the substrate. This is an especially beneficial configuration in a multi-beam system, such that each beam in the multi-beam system has its own detector, e.g. arranged around an aperture from which the primary beam is emitted from the electron-optical device towards the substrate. However, also in a single beam charged particle system, a bottom electrode of the electron-optical device may contain a detector, often specifically arranged to detect relatively high energy backscatter electrons.

Charged particle apparatus may comprise different types of detectors. A single charged particle apparatus may comprise different combinations of different types of detectors. A first example of a type of detector may comprise conversion material that convert impacting charged particles such as (signal) electrons into photons (also referred to as scintillating material), e.g. using a YAG crystal. These converted photons may subsequently be measured with an optical detector, such as a photo-diode or an array of photo-diodes. The scintillating material may, for example, be applied directly on the surface of the (array of) photo-diodes, or, for example, on a surface of an optical waveguide that may guide the photons generated by the scintillating material to the (array of) photo-diodes. A second example of a type of detector comprises sensing diodes or an array of sensing diodes that are specifically configured to directly convert impacting charged particles such as (signal) electrons into an electric signal. This electric signal is proportional to the charged particles or (signal) electrons collected. A third example of a type of detector is a charge detector and comprises one or an array of charge capture electrodes (e.g. metal plates) that capture signal particles such as (signal) electrodes which result in a charge to be measured. Especially when located close to the substrate, such charge detectors may be beneficial, as the detector surface may be integrated on the part of the electron-optical device that faces the substrate with relative ease. A fourth example of a type of detector may be configured to detect other types of interaction products, such as X-rays that may be generated by interaction of a substrate with a relatively high electron beam. The collection of X-rays in a charged particle apparatus may be used to identify e.g. the type of material that interacts with the primary beam. Collecting of signal electrons that result from the interaction of the primary beam with the part of the substrate, allows the charged particle system to generate an image representation of the part of the substrate. Such generated image representation may be used for measuring features on the part of the substrate (metrology), or may be used for recognizing defective structures or particles by comparing the image representation with a reference (inspection).

Reference is now made to FIG. 7, which schematically depicts an example configuration of a charged particle apparatus in the form of a single beam electron beam system 400. The electron beam system 400 may comprise a source, which may comprise a cathode 403, an extractor electrode 402, a gun aperture 420, and an anode 422. Electron beam system 400 may further include the electron-optical device, which in the example of FIG. 7 comprises a Coulomb aperture array 424, a condenser lens 426, a beam-limiting aperture array 435, and an objective lens assembly 432. The electron beam system 400 also comprises a detector, which in the example of FIG. 7 comprises an in-lens electron detector 444. Electron beam system 400 may comprise a substrate holder 436 supported by motorized stage 434 to hold the substrate 450, e.g. a semiconductor wafer that may be inspected or measured. It will be appreciated that other relevant components may be added or omitted, as needed.

The electron source and/or the condenser lens 426 and/or the objective lens assembly 432 and/or the beam-limiting aperture array 435 and/or the electron detector 444 may be aligned with a primary optical axis 401 of the charged particle apparatus 400. The electron detector 444 may be placed off the primary optical axis 401, along a secondary optical axis (not shown).

In the example of FIG. 7, the objective lens assembly 432 comprises a pole piece 432a, a control electrode 432b, a beam manipulator assembly comprising deflectors 440a, 440b, 440c, 440d and 440e and an exciting coil 432d. In an example imaging process, primary electron beam 404 emanating from the tip of cathode 403 is accelerated by an accelerating voltage applied to anode 422. A portion of primary electron beam 404 passes through gun aperture 420, and an aperture of Coulomb aperture array 424, and is focused by condenser lens 426 so as to fully or partially pass through an aperture of beam-limiting aperture array 435. The electrons passing through the aperture of beam-limiting aperture array 435 may be focused to form a probe spot on the surface of the substrate 450 and deflected to scan the surface of the substrate 450 by one or more deflectors of the beam manipulator assembly. Secondary electrons emanated from the substrate 450 may be collected by the electron detector 444 to form an image of the scanned area of the substrate 450.

In the objective lens assembly 432, exciting coil 432d and pole piece 432a may be configured to generate a magnetic field. In use, a part of the substrate 450 being scanned by primary electron beam 404 may be immersed in the magnetic field. Control electrode 432b, in the example of FIG. 7 being electrically isolated from pole piece 432a, may control, for example, an electric field above and on the substrate 450 to reduce aberrations of the objective lens assembly 432 and control focusing of signal electrons. One or more deflectors of the beam manipulator assembly may deflect the primary electron beam 404 to facilitate beam scanning on the substrate 450 to provide data for image reconstruction for different parts of the substrate 450.

In an alternative example of an electron beam system (not shown), there may be a aperture array provided near or at the location of the Coulomb aperture array 424 configured to convert the primary beam coming from the source into a plurality of primary beams which all may be controlled and directed by the macroscopic electron-optical device.

In another alternative example, the objective lens assembly may be fully or partially electrostatic, for example comprising one more electrostatic elements. Such electrostatic elements may comprise one more stacked plates in which one or more apertures may be defined. Such components may operate on beams as a lens, a deflector and/or a corrector. One or more of the plates may be a macro component (i.e. in which an aperture is defined for all beams), a meso component (i.e. in which an aperture is defined for a selection of all the different beams), or an aperture of each beam. An electron-optical system comprising such an objective lens assembly, or an assembly or any other part of the charged particle apparatus of the electron optical system, is shown and described in WO2022207265 2022PF00330 which is herein incorporated by reference so far in that the different electron-optical designs and the different electron assemblies comprising the disclosed electron optical devices and the electron-optical components and elements comprised therein.

Backscattered electrons (BSEs) and/or secondary electrons (SEs) may be emitted from the part of the substrate 450 upon interaction with the primary electron beam 404. In one example, a beam separator (not shown) may direct the backscattered and/or secondary electrons to a sensor surface of an electron detector. In the example of FIG. 7, the electron beam system 400 comprises an in-lens electron detector 444. The signal electrons may be captured by the in-lens electron detector 444 which is configured to generate signals (e.g., voltages, currents, etc.) that represent the intensities of the received signal electrons, and provide the signals to a processing system, such as a controller 455. The intensity of the secondary and/or the backscattered electrons may vary according to the external or internal structure of the substrate 450. By deflecting the primary electron beam 404 onto different locations of the surface of the substrate 450, different intensities are registered by the electron detector 444 from which an image may be reconstructed that reflects the internal or external structures of the substrate 450. Such images may be used for inspection and/or metrology purposes.

In some examples, controller 455 may control the motorized stage 434 to move the substrate 450 during inspection. In some examples, the controller 455 may control the motorized stage 434 to move the substrate 450 in a scanning direction continuously at a constant speed. In other examples, the controller 455 may control the motorized stage 434 to change the speed of the movement of the substrate 450 over time depending on the steps of a desired scanning process.

Any of the elements of the charged particle apparatus 400 may be prone to contamination by contamination particles or debris, especially when the substrate 450 comprises organic material (e.g. cured or uncured resist). Interaction between the charged particle beam 404 and the organic material may result in contamination (e.g. carbon deposition) on parts of the charged particle system 400. This contamination may impact the operation of the charged particle system 400. For example, electrostatic lenses typically require relatively high voltage differences across relatively small distances. If contamination or debris would be present on an element of such lenses, the contamination may trigger unwanted electrostatic discharges which may in turn damage the charged particle system 400 and/or the substrate 450. Furthermore, charged particle systems 400 often comprise relatively small apertures, either to define the beams or to generate electrostatic lenses. Contamination may reduce the size of such apertures, or may even block the apertures completely, which may impact the operation of the charged particle system 400. Deposition of contamination particles on parts of magnetic lenses may negatively affect the strength and/or shape of the magnetic field generated by such magnetic lens which may in turn negatively affect the operation of the charged particle system 400. Deposition of contamination on any of the detectors may reduce the efficiency of the detection of interaction products. Cleaning device 300 may be configured to clean any of the surfaces of the charged particle system 400 upon which contamination particles accumulate, such as the voltage shielding plate (not shown in FIG. 7). The controller 455 may be configured to control the cleaning device 300.

WO2022207265 discloses an example of a particle collection device which is herein incorporated by reference. Such particle collection devices are only disclosed by way of an example of collecting contamination particles from a substrate and/or a substrate support. Other designs and configurations of particle collection devices may be used to collect particles from any other surface of the substrate processing apparatus herein disclosed.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims.

### CLAUSES

1. A cleaning device for removing contamination particles from a lithographic surface to be cleaned, the cleaning device comprising:
an oxygen source configured to emit oxygen and thereby oxidize the contamination particles and the lithographic surface to be cleaned;
an electron source configured to emit electrons and thereby negatively charge oxidized contamination particles and the lithographic surface to be cleaned; and,
a contamination particle collector configured to receive a positive electric charge and thereby attract negatively charged contamination particles ejected from the lithographic surface to be cleaned.
2. The cleaning device of clause 1, wherein the cleaning device is configured to be positioned opposite the lithographic surface to be cleaned.
3. The cleaning device of any preceding clause, comprising an actuation system configured to generate relative movement between the cleaning device and the lithographic surface to be cleaned.
4. The cleaning device of clause 3, wherein the oxygen source, the electron source and the contamination particle collector are arranged with respect to each other such that:
the oxygen source leads the electron source in a scanning direction of the cleaning device; and,
the electron source leads the contamination particle collector in the scanning direction of the cleaning device.
5. The cleaning device of any preceding clause, comprising:
a sensor system configured to detect a cleaning parameter; and,
a controller configured to control at least one of the oxygen source, the electron source and the contamination particle collector in at least partial dependence upon the cleaning parameter.
6. The cleaning device of clause 5, wherein the cleaning parameter is at least one of the following:
a distance between the cleaning device and the lithographic surface to be cleaned;
an alignment between the cleaning device and the lithographic surface to be cleaned; and,
a relative movement between the cleaning device and the lithographic surface to be cleaned.
7. The cleaning device of any preceding clause, wherein the contamination particle collector is arranged at an angle relative to the oxygen source and the electron source such that an acute angle is formed between a direction in which the contamination particle collector faces and the lithographic surface.
8 The cleaning device of clause 7, wherein the acute angle is in the inclusive range of about 10° to about 75°.
9. The cleaning device of any preceding clause, comprising:
a first insulator located between the oxygen source and the electron source; and,
a second insulator located between the contamination particle collector and a housing of the cleaning device,
wherein the first insulator is configured to electrically isolate the oxygen source from the electron source and/or the electrons, and the second insulator is configured to electrically isolate the housing from the contamination particle collector and/or the negatively charged contamination particles.
10. The cleaning device of any preceding clause, comprising a plurality of oxygen sources, electron sources and contamination particle collectors arranged in a cleaning array.
11. A lithographic apparatus arranged to condition electromagnetic radiation and project a pattern from a patterning device onto a substrate, comprising the cleaning device of any preceding clause.
12. The lithographic apparatus of clause 11, wherein the cleaning device is configured to clean at least one of the following:
the patterning device;
the substrate; and,
an optical element configured to interact with the electromagnetic radiation.
13. A method of removing contamination particles from a lithographic surface to be cleaned, the method comprising:
oxidizing the contamination particles and the lithographic surface to be cleaned;
negatively charging oxidized contamination particles and the lithographic surface to be cleaned; and,
using a positive electric charge to attract and thereby collect negatively charged contamination particles ejected from the lithographic surface to be cleaned.
14. A method comprising:
projecting a patterned beam of radiation onto a substrate; and,
performing the method of clause 13.
15. The method of clause 14, wherein the method of removing contamination particles from the lithographic surface to be cleaned is performed during projection of the patterned beam of radiation onto the substrate.

1-15. (canceled)

16. A cleaning device configure to remove contamination particles from a surface to be cleaned, the cleaning device comprising:
an oxygen source configured to emit oxygen and thereby oxidize the contamination particles and the surface to be cleaned;
an electron source configured to emit electrons and thereby negatively charge oxidized contamination particles and the surface to be cleaned; and
a contamination particle collector configured to receive a positive electric charge and thereby attract negatively charged contamination particles ejected from the surface to be cleaned.

17. The cleaning device of claim 16, wherein the cleaning device is configured to be positioned opposite the surface to be cleaned.

18. The cleaning device of claim 16, further comprising an actuation system configured to generate relative movement between the cleaning device and the surface to be cleaned.

19. The cleaning device of claim 19, wherein the oxygen source, the electron source and the contamination particle collector are arranged with respect to each other such that:
the oxygen source leads the electron source in a scanning direction of the cleaning device; and
the electron source leads the contamination particle collector in the scanning direction of the cleaning device.

20. The cleaning device of claim 16, further comprising:
a sensor system configured to detect a cleaning parameter; and
a controller configured to control at least one of the oxygen source, the electron source and the contamination particle collector in at least partial dependence upon the cleaning parameter.

21. The cleaning device of claim 20, wherein the cleaning parameter is at least one of the following:
a distance between the cleaning device and the surface to be cleaned;
an alignment between the cleaning device and the surface to be cleaned; and
a relative movement between the cleaning device and the surface to be cleaned.

22. The cleaning device of claim 16, wherein the contamination particle collector is arranged at an angle relative to the oxygen source and the electron source such that an acute angle is formed between a direction in which the contamination particle collector faces and the surface.

23. The cleaning device of claim 22, wherein the acute angle is in the inclusive range of about 10° to about 75°.

24. The cleaning device of claim 16, comprising:
a first insulator located between the oxygen source and the electron source; and
a second insulator located between the contamination particle collector and a housing of the cleaning device,
wherein the first insulator is configured to electrically isolate the oxygen source from the electron source and/or the electrons, and
wherein the second insulator is configured to electrically isolate the housing from the contamination particle collector and/or the negatively charged contamination particles.

25. The cleaning device of claim 16, comprising a plurality of oxygen sources, electron sources and contamination particle collectors arranged in a cleaning array.

26. A substrate processing apparatus comprising the cleaning device of claim 16.

27. The substrate processing apparatus of claim 26, wherein the surface to be cleaned is a surface from which the contamination particles emanate and travel to a substrate to be processed by the substrate processing apparatus.

28. The substrate processing apparatus of claim 27, wherein the surface to be cleaned is at least one of the following:
a surface proximate a patterning device, the patterning device being configured to impart radiation with a pattern;
a surface proximate the substrate, the substrate being configured to receive a patterned radiation beam; and
a voltage shielding plate configured to protect the substrate.

29. A method comprising:
oxidizing contamination particles and a surface to be cleaned;
negatively charging oxidized contamination particles and the surface to be cleaned; and
using a positive electric charge to attract and thereby collect negatively charged contamination particles ejected from the surface to be cleaned.

30. A method of processing a substrate comprising the method of claim 29.
